(19) United States
(12) Patent Application Publication
(10) Pub. No.: US 2003/0103540 A1
(43) Pub. Date: Jun. 5, 2003

(54) Fabry-perot laser

(76) Inventor: Yu Zheng, Cupertino, CA (US)

Correspondence Address: Bo-In Lin, 13445 Mandoli Drive, Los Altos Hills, CA, 94022, US

(21) Appl. No.: 10/010,988

(22) Filed: Dec. 5, 2001

(51) Int. Cl. H01S 5/10

(52) U.S. Cl. 372/92

(57) ABSTRACT

A new low-cost Fabry-Perot (FP) laser with narrow spectral width and low sensitivity to reflections and temperature variation is disclosed in this invention. The new FP laser includes a mirror, a laser gain medium, and a partial wavelength mirror. The partial wavelength mirror has a low-cost reflective wavelength filter coating on it. The reflective wavelength filter has a narrow reflective passband width, i.e., less than 2 nm at FWHM, and a peak reflectivity of around 30% with an isolation of over 25 dB outside the reflective passband. Also the reflective wavelength filter has low wavelength thermal dependence of 0.01 nm/C or less.

### FIELD OF THE INVENTION

This invention relates generally to a method and configuration for making laser implemented in the optical transmitters for use in optical fiber signal communication systems. More particularly, this invention relates to a method and configuration for providing an improved Fabry-Perot laser at a lower cost while achieving narrow spectral width, low reflection sensitivity and reduced temperature variations.

### BACKGROUND OF THE INVENTION

Even that a Fabry-Perot (FP) laser is commonly employed in the system for carrying out the optical fiber communications, and under many circumstances, a FP laser provides useful functions and appropriate services, the FP laser is however encountered several technical difficulties. Specifically, a conventional FP laser produces laser signals with multiple resonant peaks at several wavelengths and extended over broad a spectral width, a FP laser is not suitable for applications such as wavelength division multiplexing (WDM) communications. On the other hand, a Distributed Feed-Back (DFB) laser is an improved FP laser, in which a distributed Bragg grating is put into the laser cavity of an index-guided FP laser. Due to the grating, only one mode that conforms to the wavelength of the grating can lase. Since it produces only one wavelength, a DFB laser is commonly employed for WDM communications and other applications. However, since an expensive isolator and expensive temperature control are required for a DFB laser package, a DFB laser is not practical for more economical applications that require low cost optical components. Examples of such economical applications are the optical communications systems for metropolitan access. Under many circumstances, a DFB laser is implemented in a metro access system without temperature control for cost reduction. However, an expensive isolator is still required even with coarse wavelength division multiplex applications for metro access. Therefore, the technical difficulties of reflection sensitivities and temperature dependence as now faced by those of ordinary skill in the art still impact the cost for fiber optical implementations when the DFB laser is employed.

A Fabry-Perot (FP) laser is a semiconductor laser based on a FP resonator. FIG. 1 shows the conceptual structure of a typical FP laser 10. The FP laser 10 includes a mirror 20, a laser gain medium 30, and a partial mirror 40. The pair of the mirrors 20 and 40 forms a FP cavity (resonator). The distance between the mirrors 20 and 40 is relatively short relative to the wavelength of a laser emission inducing light 50. The light 50 undergoes constructive interference within the FP cavity and then gets out from the partial mirror 40. FIG. 2 shows the output spectrum of the FP laser 10. As shown by FIG. 2, a FP laser usually produces an output light with a spectral characteristic that has several light intensity peaks at several resonant wavelengths ranging over a spectral width between 5 to 8 nm. Since its manufacturing cost is relatively low, a FP laser is commonly employed in optical fiber communications. In many situations, it can provide good services. However, since it produces many wavelengths over a spectral width, a FP laser is not suitable for applications such as wavelength division multiplexing (WDM) communications.

The difficulties encountered in a simple FP laser shown above can be solved by dispersing the unwanted wavelength before these unwanted signals reach a threshold for generating the laser emission. A DFB laser is an improved FP laser implemented with this principle. In a DFB laser, a Bragg grating is placed into the laser cavity of an index-guided FP laser. FIG. 3 shows the conceptual structure of a typical DFB laser 10′. The DFB laser includes a mirror 20′, a laser gain medium 30′, a Bragg grating 40′, and an AR coating (or a cleaved facet) 50′. Due to the grating 40′, only a one resonant mode that conforms to the wavelength of the grating 40′ is resonated with constructive interference within the cavity to generate a laser output. Thus, the spectral width of the DFB laser 10′ is greatly improved as compared to a FP laser. FIG. 4 shows the output spectrum of the DFB laser 10′. As shown by FIG. 4, a DFB laser usually produces only one wavelength. Since it produces only one wavelength, a DFB laser is commonly employed for WDM communications and other applications. However, a DFB laser has two disadvantages. First, it is very sensitive to reflections. To minimize the effects of the reflections, an expensive isolator is usually required to be packaged with it. Second, it is sensitive to temperature variations and thus expensive temperature control is usually required as part of the DFB package for applications in a dense WDM communication system. Therefore, even that DFB is able to generate laser output with superior wavelength characteristics, the cost becomes a major practical issue that prevents broad applications of DFB in fiber optical communication.

Therefore, a need exists in the art of design of a FP laser to overcome the difficulties discussed above. Specifically, an improved FB laser configuration with reduced production cost while generates a laser output with narrow spectral distributions and having a low sensitivity to reflections and temperature variations is required.

### SUMMARY OF THE PRESENT INVENTION

It is therefore an object of the present invention to provide a new and improved FP laser configuration that can be manufactured at a lower production cost while generating an output laser with narrow spectral width and operated with low reflection sensitivity and low temperature variations. The aforementioned difficulties and limitations in the prior arts can therefore be resolved by the new and improved FP laser according to the disclosures provided in this invention.

Specifically, it is an object of the present invention to provide a new FP laser configuration implemented with a narrow passband reflective filter with partial reflective mirror coated with special passband reflective coatings. The partial reflective mirror coated with special reflective passband coatings is available as low cost reflective filter. The reflective wavelength filter has a narrow passband width, i.e., less than 2 nm at FWHM. Also, the reflective wavelength filter has low wavelength thermal dependence. By employing the special partial wavelength mirror, the characteristics of the new FP laser can be greatly improved. First, as compared to a typical FP laser, the spectral width of the new FP laser is greatly improved due to the narrow passband width of the reflective wavelength filter. Second, since the reflectivity of the reflective wavelength filter is relatively high (˜30%), the reflection sensitivities of the new FP laser significantly reduced as compared to a DFB laser. Cost savings are achieved when compared to the conventional DFB lasers because for most the applications, an isolator is no longer required and the costs of operating the DFB laser with an isolator can be totally eliminated. Furthermore, the reflective wavelength filter has low wavelength thermal dependence. For most applications, the additional cost that is required for the conventional DFB laser to control the temperature can also be removed. With reduced production costs, the new FP laser can be more practically employed for wide varieties of applications even under the restrictions that a low cost system implementation is required such as applications for the coarse WDM communications for metro access.

Briefly, in a preferred embodiment, the present invention discloses a new low-cost FP laser with narrow spectral width and low sensitivity to reflections and temperature variations. The new FP laser includes a mirror, a laser gain medium, and a partial wavelength mirror. The partial wavelength mirror has a low-cost reflective wavelength filter coating on it. The reflective wavelength filter has a narrow passband width, i.e., less than 2 nm at FWHM, and its peak reflectivity is around 30% with isolation of about 25 dB outside its passband. Also, the reflective wavelength filter has low wavelength thermal dependence. When the light bounces between the mirrors and undergoes constructive interference, its spectral width is confined by the passband width of the reflective wavelength filter and thus the spectral width of the new FP laser is greatly improved. For this present application, a one-cavity reflective wavelength filter is chosen. Furthermore, due to relatively high reflectivity and low wavelength thermal dependence of the reflective wavelength filter, the new FP laser has low sensitivity to reflections and temperature variations.

These and other objects and advantages of the present invention will no doubt become obvious to those of ordinary skill in the art after having read the following detailed description of the preferred embodiment which is illustrated in the various drawing figures.

### BRIEF DESCRIPTION OF THE DRAWINGS

FIG. 1 is the conceptual structure of a typical FP laser;

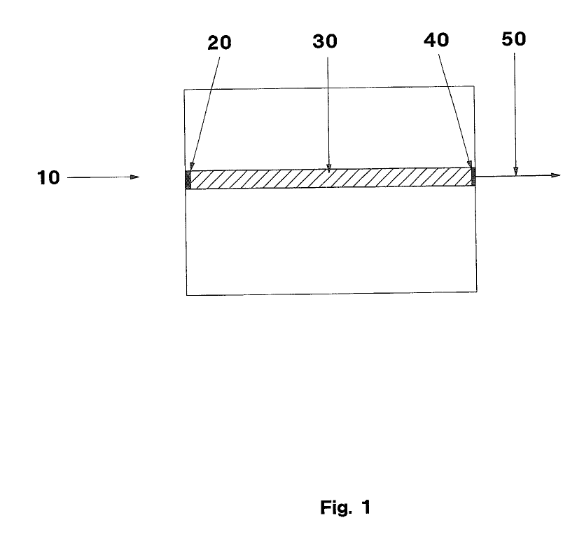

FIG. 2 is the output spectrum of a typical FP laser;

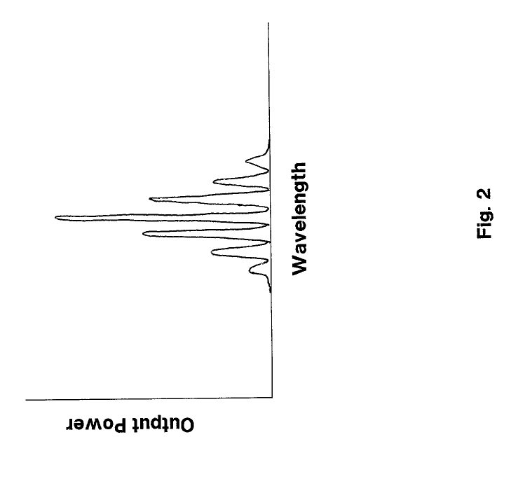

FIG. 3 is the conceptual structure of a typical DFB laser;

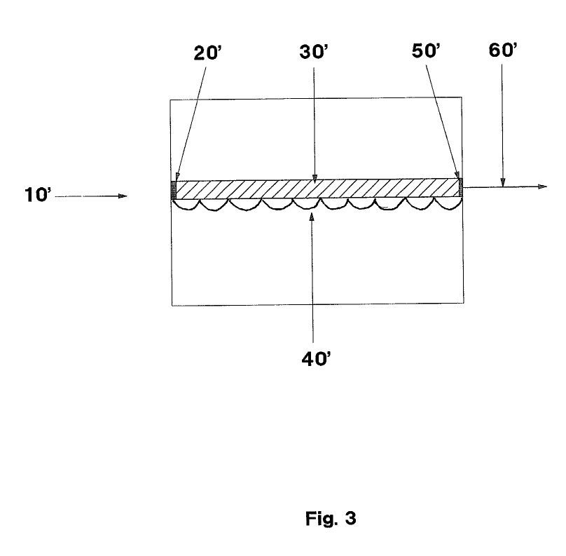

FIG. 4 is the output spectrum of a typical DFB laser;

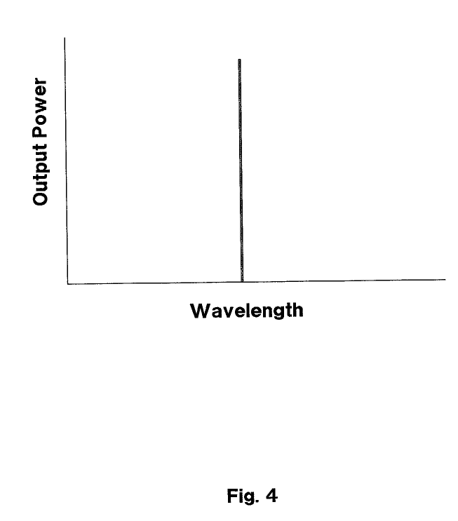

FIG. 5 is the conceptual structure of the FP laser according to the present invention;

FIG. 6 is the reflection spectrum of the partial mirror according to the present invention; and

FIG. 7 is the output spectrum of the FP laser according to the present invention.

### DETAILED DESCRIPTION OF THE PREFERRED EMBODIMENT

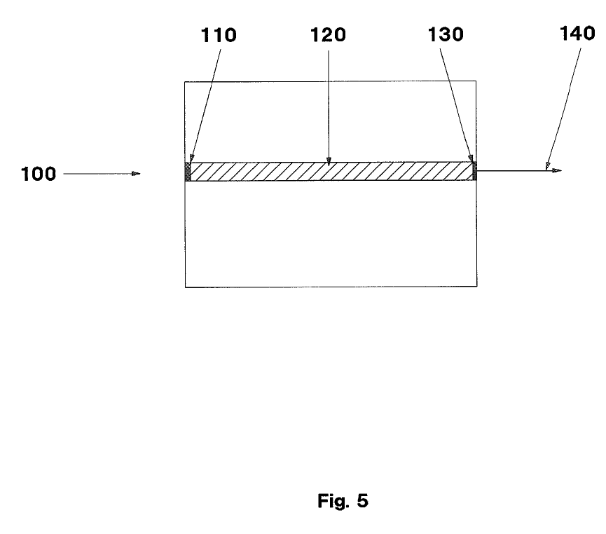

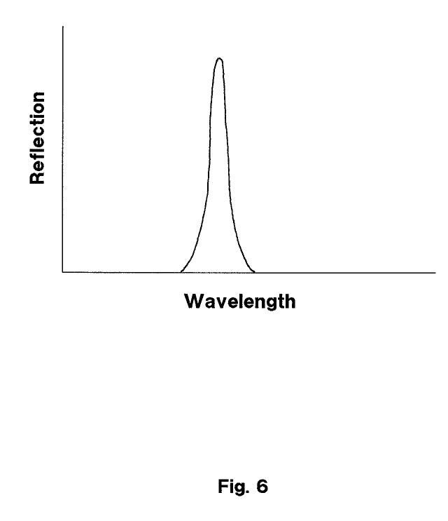

Referring to FIG. 5 for a preferred embodiment of a FP laser 100 of this invention. The new FP laser 100 includes a mirror 110, a laser gain medium 120, and a partial wavelength mirror 130. The pair of the mirrors 110 and 130 forms a special FP cavity (resonator). The partial mirror 130 is a wavelength-filtering reflective coating. FIG. 6 shows the reflection spectrum of the wavelength-filtering reflective coating 130. In the present invention, the wavelength-filtering reflective coating 130 is designed to have a narrow reflective passband width of less than 2 nm at FWHM and a peak reflectivity of around 30% having approximately 25 dB isolation outside the reflective passband. Also, the wavelength-filtering reflective coating 130 is selected to have low wavelength thermal dependence of about 0.01 nm/C or less.

Since the technology of WDM coating has achieved significant progress in the past few years, a wavelength-selective reflective coating, e.g., coating 130, with the passband characteristic, as that shown in FIG. 6, is readily available at a very reasonable price range in the market place. A mirror formed with wavelength-selective reflective coating 130 can be provided within a reasonably low price range and there would be no cost impacts due to the new configuration of employing the wavelength-selective reflective coating 130.

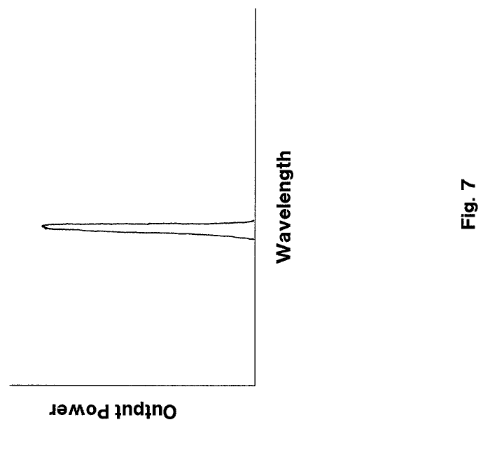

As a preferred embodiment of the present invention, the coating is coated as the mirror 130 to form a one-cavity wavelength-selective reflective filter. The portion of the signals carried in the light 140 with a wavelength outside the passband of the wavelength-selective reflective 130 are transmitted through the mirror 130 and prevented from reflecting back into the FP cavity. There would be no constructive interference for the portion of optical signals outside of the passband of the wavelength-selective reflective 130. The optical signals within the pass band of the wavelength-selective coating 130 are reflected back into the FP cavity to undergo constructive interference to produce an output laser 140 projecting out from the mirror 130. Therefore, the spectral width of the light 140 as that shown in FIG. 7 is defined by the passband width of the reflective wavelength filter 130. Furthermore, due to relatively high reflectivity and low wavelength thermal dependence of the wavelength-selective reflective coating 130, the FP laser 100 of this invention has low sensitivity to reflections and temperature variations. An isolator for preventing external optical incidence into the cavity and a temperature control mechanism to maintain the temperature within a small temperature range is no longer required for most of the applications. The FP laser can be provided with a reduced size and volume since the isolator and temperature controller are no longer necessary as part of the package. Furthermore, with the cost savings achieved by removing the requirements of isolator and temperature controller, the FP laser can be produced and implemented at a significant lower price. Large-scale implementation of FP lasers in metro-access systems at reasonably low price with improved performance in producing laser transmission of sharp and narrow output spectrum and high temperature stability over significant temperature ranges can be practically achieved with the new and improved FP laser of the present invention.

According to above descriptions, this invention discloses a Fabry-Perot laser. The FP laser includes a resonant cavity and that includes a laser gain medium 120 filling the cavity wherein the cavity having a first end and second end opposite the first end. The FP laser further includes a reflective mirror 110 with a high reflectance disposed on the first end. And, it includes a wavelength-selective reflective mirror 130 disposed on the second end. The wavelength-selective reflecting mirror 130 is implemented for selectively reflecting a portion of optical signals with a selective range of wavelengths back to the laser resonant cavity and the first mirror 110 for generating a laser through a constructive interference process in the resonant cavity. In a preferred embodiment, the wavelength-selective reflective mirror disposed on the second end includes a passband-filter reflective coating 130 for selectively reflecting the portion of optical signals with the selective range of wavelengths matched with a passband of the passband-filter reflective coating. In a preferred embodiment, the laser gain medium filling the cavity constituting an active region for generating a light. In a preferred embodiment, the passband-filter reflective coating has a passband with a width of less than 2 nm at FWHM, a peak reflectivity around 30% and an isolation of about 25 dB outside the passband. In a preferred embodiment, the passband-filter reflective coating has a wavelength thermal dependence of about 0.01 nm/C. In a preferred embodiment, the resonant cavity is an elongated cavity with the laser gain medium disposed between the reflective mirror disposed on the first end and the wavelength-selective reflective mirror disposed on the second end with a distance of N*(λ/4) therein-between wherein λ representing a peak wavelength in the selective range of wavelengths and N is an positive integer.

In a preferred embodiment, this invention further discloses a method for configuring a Fabry-Perot laser. The method includes steps of A) filling a resonant cavity with a laser gain medium. And, B) disposing a reflective mirror with a high reflectance on a first end of the cavity and disposing a wavelength-selective reflective mirror on a second end opposite the first end for selectively reflecting a portion of optical signals with a selective range of wavelengths back to the laser gain medium and the first mirror for generating a laser through a constructive interference process in the resonant cavity.

In summary this invention discloses a resonant cavity for generating an output laser. The resonant cavity includes a wavelength-selective reflective mirror 130 for selectively reflecting optical signals within a selective range of wavelength back to said resonant cavity for resonantly generating said output laser. In a preferred embodiment, this invention discloses a FP laser that includes a mirror, a laser gain medium, and a partial wavelength mirror. In a preferred embodiment, the partial wavelength mirror further has a reflective wavelength filter on it, which has narrow reflection bandwidth and low wavelength thermal dependence. This invention further discloses a method of configuring a resonant cavity for generating an output laser. The method includes a step of employing a wavelength-selective reflective mirror for selectively reflecting optical signals within a selective range of wavelength back to the resonant cavity for resonantly generating the output laser.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

We claim:

1. A Fabry-Perot laser comprising:
a resonant cavity includes a laser gain medium within said cavity wherein said cavity having a first end and second end opposite said first end; and
a reflective mirror with a high reflectance disposed on said first end and a wavelength-selective reflective mirror disposed on said second end for selectively reflecting a portion of optical signals with a selective range of wavelengths back to said laser gain medium and said first mirror for generating a laser output beam.

2. The Fabry-Perot laser of claim 1 wherein:
said wavelength-selective reflective mirror disposed on said second end includes a band reflective-filter for selectively reflecting said portion of optical signals with said selective range of wavelengths matched with a passband of said band reflective-filter.

3. The Fabry-Perot laser of claim 1 wherein:
said laser gain medium in said cavity constituting an active region for generating a light.

4. The Fabry-Perot laser of claim 1 wherein:
said band-reflective filter has a reflection band with a width of less than 2 nm at FWHM, a peak reflectivity around 30% and an isolation of about 25 dB outside said reflection band.

5. The Fabry-Perot laser of claim 1 wherein:
said band-reflective filter has a wavelength thermal dependence of about 0.01 nm/C or less.

6. The Fabry-Perot laser of claim 1 wherein:
said resonant cavity is an elongated cavity with said laser gain medium disposed between said reflective mirror disposed on said first end and said wavelength-selective reflective mirror disposed on said second end with a distance of N*(λ/4) therein-between wherein λ representing a peak wavelength in said selective range of wavelengths and N is an positive integer.

7. A resonant cavity for generating an output laser comprising:
a wavelength-selective reflective mirror for selectively reflecting optical signals within a selective range of wavelength back to said resonant cavity for resonantly generating said output laser.

8. The resonant cavity of claim 7 wherein:
said wavelength-selective reflective mirror includes a band-reflective filter for selectively reflecting said portion of optical signals with said selective range of wavelengths matched with a reflection band of said band-reflective filter.

9. The resonant cavity of claim 7 further comprising:
a laser gain medium in said cavity to function as an active region for generating a light.

10. The resonant cavity of claim 7 wherein:
said band-reflective filter has a reflection band with a width of less than 1 nm at FWHM, a peak reflectivity around 30% and an isolation of about 25 dB outside said reflection band.

11. The resonant cavity of claim 7 wherein:
said band-reflective filter has a wavelength thermal dependence of about 0.01 nm/C or less.

12. The resonant cavity of claim 7 wherein:
said resonant cavity is an elongated cavity with a laser gain medium disposed between a reflective mirror disposed on a first end and said wavelength-selective reflective mirror disposed on a second end with a distance of N*(λ/4) therein-between wherein λ representing a peak wavelength in said selective range of wavelengths and N is an positive integer.

13. A method for configuring a Fabry-Perot laser comprising:
providing a laser gain medium in a resonant cavity; and
disposing a reflective mirror with a high reflectance on a first end of said cavity and disposing a wavelength-selective reflective mirror on a second end opposite said first end for selectively reflecting a portion of optical signals with a selective range of wavelengths back to said laser gain medium and said first mirror for generating a laser output beam.

14. The method of claim 13 wherein:
said step of disposing said wavelength-selective reflective mirror on said second end comprising a step of coating a band-reflective filter having a reflective passband matching with said selective range of wavelengths for selectively reflecting said portion of optical signals with said selective range of wavelengths back to said resonant cavity.

15. The method of claim 13 wherein:
said step of providing said laser gain medium in said cavity is a step of forming active region for generating a light in said cavity.

16. The method of claim 14 wherein:
said step of coating said band-reflective filter comprising a step of coating said lens with said passband-filter reflective coating with a passband having a width of less than 2 nm at FWHM, a peak reflectivity around 30% and an isolation of about 25 dB outside said passband.

17. The method of claim 14 wherein:
said step of coating said band-reflective filter comprising a step of coating said passband-filter reflective coating has a wavelength thermal dependence of about 0.01 nm/C or less.

18. The method of claim 13 further comprising a step of:
configuring said resonant cavity as an elongated cavity having a length of N*(λ/4) wherein λ representing a peak wavelength in said selective range of wavelengths and N is an positive integer.

19. A method of configuring a resonant cavity for generating an output laser comprising:
employing a wavelength-selective reflective mirror for selectively reflecting optical signals within a selective range of wavelength back to said resonant cavity for resonantly generating said output laser.

20. The method of claim 19 wherein:
said step of employing said wavelength-selective reflective mirror includes a step of coating a band-reflective filter having a reflective passband matching with said selective range of wavelengths for selectively reflecting said portion of optical signals with said selective range of wavelengths back to said resonant cavity.

21. The method of claim 19 further comprising a step of:
providing said cavity with a laser gain medium to function as an active region for generating a light.

22. The method of claim 20 wherein:
said step of coating said band-reflective filter comprising a step of coating a band-reflective filter with a reflective passband having a width of less than 2 nm at FWHM, a peak reflectivity around 30% and an isolation of about 25 dB outside said passband.

23. The method of claim 20 wherein:
said step of coating said band-reflective filter comprising a step of coating said band-reflective filter having a wavelength thermal dependence of about 0.01 nm/C or less.

24. The method of claim 19 further comprising a step of: configuring said resonant cavity as an elongated cavity having a length of N*(λ/4) wherein λ representing a peak wavelength in said selective range of wavelengths and N is an positive integer.
